(19) United States
(12) Patent Application Publication
(10) Pub. No.: US 2004/0266086 A1
(43) Pub. Date: Dec. 30, 2004

(54) Field aperture selecting transport

(76) Inventors: Thomas D. Boone, San Jose, CA (US); Hironori Tsukamoto, New Haven, CT (US); Jerry M. Woodall, New Haven, CT (US)

Correspondence Address: Patterson Belknap Webb & Tyler, LLP, Attention: I.P. Docketing, 1133 Avenue of the Americas, New York, NY, 10036, US

(21) Appl. No.: 10/795,059

(22) Filed: Mar. 5, 2004

Related U.S. Application Data
(60) Provisional application No. 60/526,217, filed on Dec. 2, 2003.
(60) Provisional application No. 60/528,356, filed on Dec. 10, 2003.
(60) Provisional application No. 60/453,041, filed on Mar. 6, 2003.

(51) Int. Cl. H01L 29/76

(52) U.S. Cl. 438/200

(57) ABSTRACT

Novel light-emitting and/or light-responsive semiconductor devices utilize an electric field to selectively displace packets of charged carriers in an optically-active semiconductor medium. The invention, generally referred to as field aperture selecting transport or “FAST,” provides a new way to overcome the recombination-imposed speed limits associated with traditional light-emitting semiconductor devices.

### CROSS-REFERENCE TO RELATED APPLICATIONS

This application claims priority from the following U.S. provisional patent applications: Ser. No. 60/526,217 (“Field Aperture Selecting Transport Light Emitting Device”); Ser. No. 60/528,356 (“High-Speed Optical Modulation Techniques Incorporating Heavy Doping and Lateral Drift Transport”); and Ser. No. 60/453,041 (“Semiconductor Optical Routing Device”). Each of the aforementioned provisional applications is incorporated herein by reference.

### FIELD OF THE INVENTION

The present invention relates generally to methods/devices for optical emission, modulation, switching, etc., and more specifically to techniques for improving the cost/performance of such devices through utilization of a novel carrier transport process.

### BACKGROUND OF THE INVENTION

Historically, the seminal optical emitters used in fiber optic data links were the light-emitting diodes (“LEDs”) developed in a GaAs compound semiconductor material. (See H. Rupprecht, J. M. Woodall, K. Konnerth, and D. G. Pettit, “Efficiency Electroluminescence from GaAs Diodes at 300 K,” Applied Physics Letters, v.9, n.6, p221, 1966.) But the advent of the semiconductor laser diode, with its superior power/modulation bandwidth product, sub-nanometer emission linewidth, and highly directional output, resulted in the eventual replacement of LEDs in the highest performance fiber optic systems. Recently, however, the emergence of the “information age” has ushered in higher demand for more economical fiber networks, which has resulted in a reexamination of the cost of components (i.e., multi-mode fibers, fiber connectors, optoelectronic emitters, photodetectors, amplifiers, etc) used in fiber networks.

Currently, microprocessor front-side bus clock speeds in excess of 1 GHz are available and are expected to increase beyond 10 GHz. However, as we approach the fundamental limits of photolithography, significant performance enhancements will require multi-chip computer architectures. But multi-chip systems require interconnects operating at data rates near the clock speed of the processor. At these bus speeds, crosstalk between interconnects and electromagnetic interference will be detrimental to total system performance. Optical interconnects, however, are not nearly as susceptible to these issues. Additionally, the continued development of planar optical waveguides could result in the utilization of the top surface of a chip as the main input/output node for interconnection, enabling the consideration of more flexible schemes for integration and thermal management.

In the past, the most significant technology driver for high-speed optoelectronic components has been the demands of the long-haul optical fiber telecommunication industry. Extraordinary performance has been achieved leading to currently available serial products operating in excess of 40 Gbit/s. However, the cost requirements of the consumer electronics industry are quite restrictive compared to those of the telecommunication industry. A single laser-based transceiver for a 40 Gbit/s system can cost in excess of $40,000 and 10 Gbit/s transceivers well over $1,000. With computer cost already less than $1000, significant cost reductions are critical to integrating optical interconnect technology into the mainstream computer market.

LEDs represent an economically attractive alternative to laser diodes for low-cost consumer applications. Compared to laser diodes, LEDs are easier to fabricate due to their reduced complexity in physical structure and epitaxy. LEDs require less complex driver and supporting electronics. LEDs can operate at lower electrical powers since they are not required to achieve a threshold current to operate. The delay in the large-signal rise time associated with achieving a population inversion in a laser diode is also not present in an LED. And LEDs do not suffer from the relaxation oscillation that lasers experience during switching transients.

Additionally, LEDs are not subject to mode-hopping. In laser diodes, slight changes occur in the laser cavity length and the index of refraction during laser operation due to thermal stress caused by high current densities. The resulting perturbation of the effective resonance condition causes the emission peak to shift from mode to mode and dynamic spectral shifts to appear in the output signal. To prevent this effect, the temperature of the laser must be carefully monitored and controlled. Since LEDs are broad-spectrum devices, mode-hopping does not occur and cooling is only necessary to prevent damage to the device at high operating powers.

LEDs also offer advantages in terms of ease of integration with other microelectronic circuitry. LEDs are surface emitting, which is not only beneficial for direct wafer testing, but also enables them to be integrated into an array or microelectronic/optoelectronic circuit more easily than laser diodes. Although the development of vertical cavity surface emitting lasers (“VCSELs”) has somewhat diminished this advantage, VCSELs still pose substantially greater integration challenges than LEDs. Unlike LEDs, VCSELs require the growth of relatively thick, complex distributed Bragg reflectors (“DBRs”), which makes integration of these structures into a microfabricated circuit process challenging due to the relatively tall DBR mesa step-heights.

In LEDs, a PN junction electrically injects electrons or holes across a depletion region, where they are likely to recombine with carriers of the opposite charge. In a direct bandgap semiconductor, this recombination will typically result in photon emission. The average time for carrier recombination to occur will affect the temporal response of the photonic signal. The material parameter associated with this average recombination time is typically referred to as the minority carrier recombination lifetime. As this lifetime decreases, the LED's optical rise- and fall-time decreases, resulting in narrower pulsewidth capabilities. LEDs in high-speed data links are required to emit trains of short optical pulses to represent digital data. The photonic signals' temporal pulse width ultimately determines the system's bandwidth. Therefore, in an LED-based link, minority carrier lifetime directly limits the maximum high-speed performance. LED functionality is essentially a fortuitous result of the PN junction diode carrier dynamics in a direct-bandgap semiconductor. The carrier action of a basic homojunction LED is illustrated in the band diagram in FIG. 1. Note that when a p-type and n-type semiconductor form a junction, the mobile majority carriers in the semiconductors attempt to redistribute themselves equally throughout the entire semiconductor by diffusion. The effect is similar to that of the diffusion dynamics of a gas distributing itself equally in a room. However, the oppositely charged immobile dopant ions create a columbic force resulting in a potential difference that counteracts this redistribution process. Eventually, an equilibrium condition exists where carriers being repelled by the ionized impurities counter the diffusion process. This produces a depletion region (substantially free of mobile carriers) that effectively isolates the two doped quasi-neutral regions. The carrier diffusion barrier formed by the depletion region is compensated for when an external voltage is applied to the device. The forward bias voltage results in the injection of minority carriers into the quasi-neutral regions. If the width of the quasi-neutral region is much less than the minority carrier diffusion length of the semiconductor:

L_{D}:=\sqrt{D·τ}

where D is the diffusion coefficient and τ is the minority carrier recombination lifetime, most of the minority carriers will reach the electrode and flow into the external circuit before they have the opportunity to recombine. However, if the quasi-neutral region is wider than LD, most of the minority carriers will recombine with the majority carriers. The recombination process in a high quality direct bandgap semiconductor will result in photon generation.

GaAs homojunction diodes doped with Silicon were the first high-efficiency LEDs demonstrated (Rupprecht, et al., supra), and were substantially more efficient than those previously developed in other material systems. The technological enabler that facilitated this enhancement was the utilization of Silicon as an amphoteric dopant. Silicon, a group IV element, will dope an III-V compound semiconductor either p-type or n-type. Thus, for Silicon to dope GaAs n-type or p-type is dependant on whether it substitutes for a Ga site or an As respectively. The internal efficiency was high due to the quality of the liquid phase epitaxy (LPE) grown material. Additionally, the variation in the Si activation energy resulted in a slightly lower luminescence emission center wavelength for the p-type region and a higher energy absorption edge for n-type region. Therefore, the emission from the p-type layer did not suffer from significant self-absorption in the n-type layer. If the LED's light emission was observed through the n-type side, luminescence efficiency was increased considerably. Although these devices are not suitable for today's high-speed link applications, they did enable the development of early television remote control links.

Several high-speed limitations exist in homojunction LEDs. In a homojunction device, light is generated on both sides of the junction. But fiber optic system need narrow linewidths. Given that each side of a homojunction LED has a slightly different emission spectrum, the linewidth of the total emission is rather broad. Limitations also exist on maximum doping with Silicon, which restricts the ultimate speed of these devices. Additionally, since both minority-carrier electrons and holes are used to create light, the transport characteristics of both carrier types must be considered during transient operation. Typically, holes have a significantly larger effective mass than electrons, resulting in a lower mobility and longer recombination lifetimes. The operative result in an LED is less efficient current injection and slower optical pulse generation in the n-type side. Furthermore, the quasi-neutral regions are required to be wider than the carrier diffusion lengths for efficient optical generation, which results in a considerable amount of self-absorption within the light-emitting layers. The effect is somewhat counteracted by photon recycling, which is the subsequent reemission of a photon after previously being absorbed. However, this effect only occurs appreciably in the highest quality materials, and further increases the total effective lifetime, which reduces the overall modulation speed of the device.

An additional disadvantage of the homojunction results from a materials characteristic of GaAs. Fermi level pinning at the surface of compound semiconductors has been studied (See J. L. Freehouf, A. C. Warren, P. D. Kirchner, J. M. Woodall, and M. R. Melloch, “Surface Fermi Level Engineering—or There's More to Schottky Barriers Than Just Making Diodes and Field Effect Transistor Gates,” Journal of Vacuum Science & Technology B, v.9, n.4, pp2355-2357, July-August 1991). Although the actual mechanism is still debated, the effective work function model suggest that the formation of point defects due to excess As on the surface is the cause of the invariance of the Fermi level. The culmination of this effect is that the Fermi level for GaAs is pinned mid-gap at the surface of a GaAs wafer. In doped GaAs, this pinning effect results in significant band bending near the surface of the semiconductor (see FIG. 1, showing “forward bias” state). GaAs midgap band bending produces an internal electric field that sweeps minority carriers to the surface on either p-type or n-type wafers. Carriers that are swept to the surface will be non-radiatively trapped by surface states caused by defects or impurities adhering to the surface (and, as a result, will recombine with no light emission). Incorporation of heavy doping near the surface of the semiconductor has been shown to reduce the deleterious effects due Fermi-level pinning (see T. J. DeLyon, J. A. Kash, S. Tiwari, J. M. Woodall, D. Yan, and F. H. Pollak, “Low Surface Recombination Velocity and Contact Resistance Using P⁺/P Carbon Doped GaAs Structures,” Applied Physics Letters, v.56, n.24, pp. 2442-2444, Jun. 11, 1990.). However, for LED applications, development of the heterojunction device (described next) has proved superior.

One of the more significant advancements in LED technology was the successful development of the GaAs/AlGaAs heterojunction (see H. Rupprecht, J. M. Woodall, and G. D. Pettit, Applied Physics Letters, v. 11, n.91, 1967). First envisioned by Shockley and later promoted by Kromer, the successful growth by Woodall of this heterojunction resulted in the single and double heterojunction LEDs (see Woodall, Rupprecht and Reuter, “Liquid Phase Epitaxial Growth of Gaₗ₋ₓAlₓAs,” Journal of Electrochemical Society, v.116, n.6, p.899, 1969.). The double hetrojunction LED (“DH-LED”) was far superior to traditional homojunction LEDs because of its ability to confine the recombination of carriers to a much smaller, defect-free region and selectively determine the type of minority carrier injected. FIG. 2 illustrates the band diagram and the functionality of a p-type double heterojunction LED. In this device, electrons can be rapidly injected into a p-type active region, while the majority carrier holes are confined to the active region and precluded from injection back into the source region. The heterojunction on the right acts as barrier to electron diffusion beyond the light-emitting “active” region, and confines carrier recombination to a much thinner layer. Typically, the active region in a DH-LED is significantly narrower than that found in a homojunction device, which has the effect of significantly reducing self-absorption and increasing modulation speed by reducing the time needed to fill the active region. Since the AlGaAs bandgap energy is greater than that of GaAs, the absorption edge is a much higher energy, and the AlGaAs functions as a transparent window to the GaAs luminescence. The AlGaAs/GaAs heterostructure is lattice matched, resulting in a high quality interface with a low density of surface states. While it is difficult to eliminate every interface state in a heterostructure, the recombination velocity at the AlGaAs/GaAs interface is reduced appreciably from the bare GaAs pinned surface, resulting in much higher photon conversion efficiency.

Development of the DH-LED led to significant advancements in laser diodes, as well. Laser diodes are merely LEDs with a number of additional features and operating characteristics. The GaAs active layers are grown thin (<1000 Å) between wider-bandgap AlGaAs, which results in quantum confinement within the energy bands. Thus, the luminescence emission spectrum is much narrower than with an LED. Additionally, the active region is typically lower doped than an LED to more easily achieve the required population inversion necessary to achieve gain by stimulated emission. Finally, the gain region must be placed in a resonant cavity, so that a single wavelength will be intensified. The formation of the resonant cavity is one of the more challenging parts of the laser diode construction, and contributes significantly to the total fabrication cost of the device. Using the semiconductor/air interface, the semiconductor is precisely cleaved to create mirrors directly from the crystal for the laser cavity. Accurate crystal cleaving is a laborious, time consuming process and must be precisely controlled to create the correct cavity length. Additionally, this process eliminates any option to perform on-wafer testing of functional devices.

The subsequent development of VCSELs has reduced the post-growth processing of the laser diodes by directly incorporating the resonant cavity into the grown device. Cleaved mirrors are replaced with distributed Bragg reflectors, grown with alternating GaAs/AlGaAs heterostructures. VCSELs have been fabricated using metallic top reflectors (see E. F. Schubert, H. S. Luftman, R. F. Kopf, R. L. Headrick, and J. M. Kuo, “Low Threshold Vertical Cavity Surface Emitting Lasers With Metallic Reflectors,” Applied Physics Letters, v.57, n.2, pp 117-119, July 1990.). VCSELs are processed with relatively straightforward photolithographic techniques in a manner similar to LEDs. Their surface-emitting nature also enables them to be fully tested on the wafer. However, there are still several performance limitations to these device structures. VCSEL performance is quite sensitive to the resonant cavity design and fabrication. The DBR growth is very sensitive and the device yield across the wafer can be limited by the restrictive homogeneity demands. Since the cavity is perpendicular to the growth layers, the gain regions for VCSELs are extremely thin and the total output power capabilities of these devices are much lower than laser diodes. Multiple quantum wells have been implemented in an attempt to increase the total output power capabilities. However, this again increases the device complexity and eventually the total fabrication cost. Finally, the DBR stacks result in a relatively tall topographical device. Because future optical circuit applications will most likely demand considerable microelectronic, optoelectronic and photonic integration, the VCSEL's large mesas will not be ideal for integration or waveguide coupling.

One issue that affects LED design is “extraction efficiency”—that is, the ability of generated photons to avoid internal reflection and escape from the device. As illustrated in FIG. 3, the critical angle for internal reflection in a GaAs LED is approximately 12 degrees. (This is derived by applying Snell's law to the GaAs-air interface.) As a result, losses associated with total internal reflection pose a serious detriment to LED efficiency. FIGS. 4a-c depict several techniques for increasing the extraction efficiency of an LED. The first technique, surface texturing, is illustrated in FIG. 4a. Surface texturing seeks to improve light extraction efficiency by roughening the top surface of the device and incorporating a reflective bottom surface. The roughened surface has the effect of randomizing the escape cone. Rays are reflected at different angles each time they reflect off the roughened surface. After being reflected by the bottom surface, they have a second opportunity to fall into the randomized escape cone. The process continues until the photon is transmitted through the top surface or reabsorbed by the semiconductor. This technique has been coupled with the photon recycling to create very high external efficiencies (see Schnitzer, E. Yablonovitch, C. Caneau, T. J. Gmitter, and A. Scherer, “Ultrahigh Spontaneous Emission Quantum Efficiency, 99.7 Percent Internally and 72 Percent Externally From AlGaAs/GaAs/AlGaAs Double Heterostructure,” Applied Physics Letters, v.62, n.2, pp131-133, Jan. 11, 1993).

A technique referred to as natural lithography has been utilized to increase the extraction efficiency of LEDs by randomizing the surface (see Schnitzer, E. Yablonovitch, C. Caneau, T. J. Gmitter, and A. Scherer, “30 Percent External Quantum Efficiency from Surface Textured, Thin Film Light Emitting Diodes,” Applied Physics Letters, v.63, n.16, pp2174-2176, Oct. 18, 1993). Natural lithography utilizes a thin-film slurry of Styrofoam balls of a size on the order of the wavelength of the light. The slurry is deposited on the surface of the device, and then the structure is acid etched while the thin film slurry is still in contact. The slurry acts as a etch mask, and creates a randomized pitted/roughened surface. Using natural lithography, external extraction efficiencies have been reported s as high as 72% (Schnitzer et.al., January 1993). Natural lithography was implemented in a high-speed LED that observed 29% external efficiency at a bandwidth over 1 Gbit/s (see R. Windisch, A. Knobloch, M. Kuijk, C. Rooman, B. Dutta, P. Kiesel, G. Borghs, G. H. Dohler, and P. Heremans, “Large-Signal-Modulation of High-Efficiency Light-Emitting Diodes for Optical Communication,” IEEE Journal of Quantum Electronics, v.36, n.12, December 2000[2001?]).

An in-situ approach to creating the roughened top surface has been reported (see T Hastings, “LED External Emission Increase Incorporating Cross-Hatch,” Masters Thesis, Purdue University, 1997). The technique utilizes the crosshatch pattern created by growing lattice mismatched InGaAs on GaAs. The crosshatch is a result of threading dislocations that occur due to the lattice mismatch at the surface of the GaAs/InGaAs heterostructure. In this technique, a thin-film liftoff was performed, and the devices were mounted on a backside mirror. An extraction efficiency of close to 10% was observed. Another technique for increasing extraction efficiency involves use the resonant cavity LED (“RCLED”) structure (see FIG. 4b). In this structure, the cavity modifies the optical density of states such that more allowed modes fall within the escape cone. RCLEDs are fabricated with top and bottom reflectors around the active region to form the cavity. An additional benefit is the cavity narrows the linewidth, reducing the effects of chromatic dispersion. Also, coupling efficiency to optical fibers is improved due to the directionality associated with RCLED emission. Like in VCSELs, the resonant cavity typically is incorporated into the RCLED by growing DBR mirrors below and above the LED active region. Initially, it might appear that the cost advantage of a less sophisticated growth technique is lost. However, the resonant cavity requirements are relaxed for an RCLED compared to the demands of a VCSEL. RCLEDs fabricated using thin film liftoff and metal mirrors have achieved a two-fold improvement in extraction efficiency and directionality (see R. Zhu, “Metal Mirror RCLED,” Ph.D. Dissertation, Purdue University, 1999).

One of the more expensive approaches to increasing the extraction efficiency is packaging techniques. For high-brightness LED applications, the active layers can be etched into very complex pyramidal geometries (see M. R. Krames, M. Ochiai-Holcomb, G. E. Hofler, C. Carter-Coman, E. I. Chen, I. H. Tan, P. Grillot, N. F. Gardner, H. C. Chui, J. W. Huang, S. A. Stockman, F. A. Kish, M. G. Craford, T. S. Tan, C. P. Kocot, M. Hueschen, J. Posselt, B. Loh, G. Sasser, and D. Collins, “High-power truncated-inverted-pyramid (AlxGa1−x)0.5In0.5P/GaP light-emitting diodes exhibiting >50 external quantum efficiency,” Applied Physics Letters, v.75, n. 16, pp.2365-2367, Oct. 18, 1999). External quantum efficiencies of 32.6% and 55% for post-epoxy encapsulation were reported. The demands for low capacitance in a high-speed system preclude these options from consideration since the device capacitance is highly dependent on device geometry. However, encapsulation in index matching materials coupled with the fabrication of micro-lenses (see FIG. 4a) remains a viable option for increasing extraction efficiency. Research on the techniques for the microfabrication of these lenses is ongoing and less expensive processes and structures could be available in the near future.

Another technique that can be used to decrease the effective rise-time of an LED is pre-emphasis. As illustrated in FIG. 5, pre-emphasis incorporates a larger amplitude pulse at the beginning of the device drive current. Pre-emphasis is currently being utilized in the automotive industry to increase the speed of LEDs for in-car fiber links. Typically, LED drive signals are maintained below 1000 A/cm². However, damage thresholds for devices are not clearly understood for short-transient stresses on the order of picoseconds.

The fall-time is unaffected by the pre-emphasis, and still decays as a function of carrier lifetime. However, as depicted in FIG. 6, the fall-time of the LED can be decreased by utilizing a negative current pulse at the end of the drive signal to effectively pull carriers out of the active region. This technique involves a much more complicated circuit to create the negative polarity and large slew rate necessary to create the reverse pulse. To succeed, the conduction band offset between the emitter and the active region must be carefully designed and grown. The conduction band offset will preclude carriers from easily flowing out of the active region and careful compositional grading will be necessary during the growth of the emitter/active region heterostructure. Nevertheless, faster fall-times have been reported utilizing this post-emphasis technique.

Ultimately, the primary materials-based limitations to high-speed LED performance are related to the minority carrier recombination lifetime and the maximum allowed injection current. For a given rectangular current pulse, rise- and fall-times are limited by the recombination lifetime, which can be controlled by both doping and injection current amplitude. Once the injection current into the LED active region ceases, remaining minority carriers recombine spontaneously in an exponential decay that reduces their concentration by 66% in the time τ_{rad}. Thus, the fall-time of the optical signal in a standard DH-LED is strictly a function of the lifetime τ_{rad}. Here lies the motivation for continued study of the dynamics of the minority carrier lifetime and the investigation of novel techniques for reducing the τ_{rad}.

The techniques for enhancing LED high-speed characteristics have focused primarily on decreasing the minority carrier lifetime by doping, or by driving the device into stimulated emission (see, e.g., Windisch et. al, 2001). Focusing on devices with bandwidth beyond 1 Ghz, an IBM effort reported GaAs LEDs with a 1.6 GHz cutoff frequency (see T. J. deLyon, J. M. Woodall, J. A. Kash, D. T. McInturff, R. J. S. Bates, P. D. Kirchner and F. Cardone, “Minority Carrier Lifetime and Photoluminescent Response of Heavily Carbon-doped GaAs Grown With Gas Source Molecular-beam Epitaxy Using Halmethane Doping Sources” J. Vac. Sci. Technol. B, v.10, n.2, April 1992). These LEDs were determined to be limited by minority carrier lifetime, and contained active regions doped with carbon to N_{A}=1-2×10¹⁹ cm⁻³. At the time, these devices had the highest reported 3 dB-frequency, but they suffered from very low output power. The reported internal quantum efficiency (IQE) was only 2%. A group at Purdue University surpassed this performance record with a cutoff frequency of 1.7 GHz and an improved IQE reported to be 10% (see C. H. Chen, M. Hargis, J. M. Woodall, and M. R. Melloch, “GHz Bandwidth GaAs Light-emitting Diodes,” Applied Physics Letters, v.74, n.21, pp. 3140-3142, March 1999). These LEDs were also lifetime limited, and incorporated a GaAs DH-structure active region doped with beryllium to N_{A}=7×10¹⁹. The same group reported that an LED doped at N_{A}=2×10¹⁹ had a cutoff of 440 MHz and a significantly improved IQE of 80%.

In 2000, a European collaboration reported a I Gbit/sec bit rate from a device with a 3 dB frequency near 250 MHz (see R. Windisch, A. Knobloch, M. Kuijk, C. Rooman, B. Dutta, P. Kiesel, G. Borghs, G. H. Dohler, and P. Heremans, “Large-Signal-Modulation of High-Efficiency Light-Emitting Diodes for Optical Communication,” IEEE Journal of Quantum Electronics, v.36, n. 12, December 2000). They incorporated a thin active region (d=30 nm) to easily achieve high-level injection. They also utilized natural lithography to incorporate a textured surface to improve external quantum efficiency. They observed efficiencies as high as 29% for the 1 Gbit/sec device. However, at 2 Gbits/sec, the device external quantum efficiency fell sharply to 2.5%. The explanation given for this reduction in efficiency was non-radiative recombination and carrier spillover.

Recent work reported by Koudelka et. al. utilizes internal electric fields to rapidly drift carriers into and out of a narrow light-emitting active region (see R. D. Koudelka; J. M. Woodall; E. Harmon, “Novel light emitting device with ultrafast color switching,” International-Electron-Devices-Meeting, 2002; see also U.S. Pat. No. 6,607,932, “High modulation frequency light emitting device exhibiting spatial relocation of minority carriers to a non-radiative recombination region,” to Woodall and Koudelka). This approach—which applicants do not concede as prior art to the present invention—stores carriers close to the active region during the off cycle so they only have to drift a short distance to excite the luminescence. In this device, speed is not limited by the recombination time, but by the speed at which excess carriers can be removed from the active region with an electric field. Effective fall times observed using this technique were less than 60 ps.

In sum, there clearly exists a need for improved light-emitting devices that can be economically fabricated, yet do not suffer from the radiative lifetime-based speed limitations of traditional approaches. The invention, as described below, addresses these needs.

### DESCRIPTION OF THE INVENTION

In light of the above, one object of the invention relates to a modulation technique (referred to as field aperture selecting transport or “FAST”) that utilizes lateral carrier drift and optical exit apertures or pathways defined on the semiconductor's surface to overcome the radiative recombination lifetime limitation of traditional semiconductor light emitting devices.

Another object of the invention relates to a new class of high-speed light emitting semiconductor devices for use in optical data transmission systems.

Yet another object of the invention relates to optical FAST-based optical emitter devices.

A still further object of the invention relates to FAST-based optical switching or routing devices.

A yet still further object of the invention relates to a FAST-based technique for high-speed parallel-to-serial conversion of a parallel optical input signal.

Additional objects, advantages, and applications of the invention will become apparent in light of the summary, description, figures, and claims that follow.

In accordance with one embodiment, a FAST-based emitter/modulator utilizes an electric field to transport a packet of minority carriers across an optical output aperture defined on the surface of a semiconductor. A short burst of light is allowed to escape through the surface of the device as the packet drifts past the opening or aperture. To first order, the temporal length of the optical pulse will be a function of the width of the excess minority carrier packet, the width of the aperture, and the drift velocity of the excess minority carriers. In p-type GaAs, geometric scales of 5 μm should make possible pulse widths near 100 ps.

Minority carriers may be electrically injected into the semiconductor by forward biasing a pn junction or through a point contact. Alternatively, minority carries may be generated directly within the semiconductor by optically pumping the material with an external light source with a photon energy greater than the bandgap energy of the semiconductor. When a constant optical pumping source illuminates a region of a semiconductor, an equilibrium distribution of electrons or holes is created (i.e., the number of excess minority carriers becomes constant). This equilibrium occurs when the generation of minority carriers caused by the absorption of the pumping source light is in balance with the recombination of the minority carriers with majority carriers resulting in optical emission with a photon energy near the bandgap energy of the semiconductor—a phenomenon is commonly referred to as excitation photo-luminescence (“PL”).

FAST devices rely on the fact that a light-emitting distribution of minority carriers is electrically charged (i.e., negative for electrons or positive for holes). Therefore, such a distribution may be spatially displaced by an electric field. (This type of carrier dynamic is referred to as drift, and the velocity at which these carries move in the electric field is referred to as the drift velocity. Drift velocity is typically equal to the product of the electric field intensity and the semiconductor mobility, but eventually reaches an upper limit called the saturation drift velocity.) In a FAST device, a distribution of minority carriers can be advantageously displaced from a position of initial carrier generation in accordance with the drift principle and the minority carrier recombination lifetime of the semiconductor.

For example, in one preferred embodiment of the invention, an optical source with a photon energy greater than the bandgap energy of a p-type GaAs semiconductor is utilized to generate aminority carrier distribution within a region of the semiconductor. This creates a PL distribution (or packet) of electrons within the semiconductor (see FIG. 7A). By applying an oscillating voltage across electrical contacts on the surface of the semiconductor device, the photoluminescence (“PL”) distribution will oscillate horizontally back and forth between the electrical contacts (see FIGS. 7B-C). Once a region between the contacts is defined as an optical exit pathway (e.g., by providing a coupled optical fiber, grating, relief in opaque material, etc), an external optical pulse will be generated every time the PL distribution drifts by the aperture. The temporal length of the optical pulse will be determined by the drift velocity of the PL distribution, the width of the PL distribution, and the width of the exit aperture. Using this technique, very fast optical pulses can be generated by quickly switching the polarity across the contacts. By coding these polarity changes digitally, the device can be used as a fast optical emitter.

Opaque contacts may also be used to define, in whole or in part, the exit aperture or output-coupling pathway from a FAST device. Consider the output aperture defined by two opaque electrodes deposited on a direct bandgap p-type semiconductor (see FIGS. 8A-D). Under zero bias conditions, an excitation laser focused in the center of the opening will photo-generate a packet of electron-hole pairs. The resulting photoluminescence spot (due to recombination) will appear through the top surface roughly in the same location as the laser's focus (FIG. 8A). However, applying a bias voltage between the two electrodes creates an electric field that accelerates the electrons to a velocity v_{d}=μₙ E, where E is the lateral electric field intensity and μₙ is the electron mobility. While the bias is applied, the electrons continue to drift from their generation position toward the positive electrode until they eventually recombine with a hole, which results in an overall shift of the excess minority carrier distribution toward the positive contact. If a majority of the electrons are transported under the electrode before they recombine, contact shadowing will effectively block the external light emission (FIG. 8B). If the internal electric field due to the applied voltage is large enough, the drifting and shadowing process can produce a faster extinction of the light emission than the typical decay due to the minority carrier lifetime. When the applied voltage is returned to zero, the external PL emission intensity in the photo-pumped region rapidly increases in time as a function of the minority carrier lifetime. Therefore, a fast optical falling edge can be realized by rapidly removing photo-generated carriers from the optical exit aperture or pathway using a fast electrical pulse.

A second modulation technique utilizes a differential applied voltage and carrier storage during the shadowing process to create the external light pulse. When the polarity of the voltage is switched, the electron drift will reverse directions and begin to flow toward the opposite contact. The electrons that were shadowed by the first contact, and have not yet recombined, now drift underneath the aperture, and the PL emission due to this packet will once again be allowed to transmit through the surface (FIG. 8C). Naturally, the light will be blocked again once the majority of the recombining electrons drift under the second contact (FIG. 8D). This drifting and shadowing process results in an external burst of light for the period of time that the recombining packet is positioned within the window region. An interesting attribute of this technique is that it requires only a fast differential rising or falling electrical edge (e.g. +V→−V) to generate the light pulse, rather than a short return-to-zero single ended electrical pulse. This packet drift technique can produce shorter PL emission rise-times than those produced by the single ended voltage technique. In GaAs, the saturation drift velocity is in excess of 1×10⁷ cm/s. Consequently, one can conclude that if the concept were employed at this velocity with a 5 μm wide aperture opening, the external light pulse generated would be approximately 100 ps in width, which is consistent with 10 Gbit/s operation.

Of course, the invention is appropriate for use in single-mode and multi-mode fiber optic systems, as well as free-space data transmission systems.

One application of the FAST invention involves its use in an all-optical routing device. FIG. 9A, for example, shows a device that permits an optical signal, conveyed on a centrally-located input fiber, to be selectively routed to any of four peripherally-mounted output fibers. The optical input signal excites a packet of minority carriers in the semiconductor. Depending upon the voltage bias applied across the electrodes, FAST action can be used to selectively drift the excited minority carrier packets to an appropriate output coupling region, for example the leftmost region (FIG. 9B), the rearmost region (FIG. 9C), the foremost region (FIG. 9D), or the rightmost region (FIG. 9D). Because selection of the target output regions requires only a rapid change in differential electrode potential(s) and the resulting drift of the carriers, this routing device permits very high-speed (e.g., nanosecond scale) switching.

Another application of the invention relates to optical parallel-to-serial conversion. As exemplified in FIG. 10, parallel channels write data to a FAST structure through n parallel emitters. Once carriers are generated, an applied bias sweeps the packets down the FAST structure at speeds approaching the saturation drift velocity of the semiconductor. At a defined output aperture, a series of temporal pulses appears, thus completing the parallel-to-serial conversion.

Focusing, now, on specific aspects of the instant invention, one aspect relates generally to methods for modulating optical emissions from a semiconductor device by, for example: (a) providing an excitation that produces an illuminating packet of charged carriers; (b) selectively positioning the packet to increase optical emissions from the semiconductor device; and (c) selectively positioning the packet to reduce optical emissions from the semiconductor device. One or both of steps (b)-(c) may be achieved by selective application of an electric field (and, optionally, a magnetic force) to the packet. Steps (b) and/or (c) may be repeatedly performed, in an order determined by an electrical input signal, to produce an optically modulated output signal corresponding to the electrical input signal. Providing an excitation may involve pumping the semiconductor device with a continuous laser excitation, pumping the semiconductor device with a pulsed laser excitation, and/or electrically pumping the semiconductor device. Step (b) may involve selectively positioning the packet so that its optical emissions for the semiconductor device are substantially unblocked, selectively applying an electric field that positions the packet in a position that allows substantial emission from the semiconductor device, ceasing application of an electric field to allow the packet to drift to an equilibrium position that allows substantial emission from the semiconductor device, and/or selectively positioning the packet in substantial alignment with an energy pathway through which optical emissions can escape from the semiconductor device. The energy pathway may include an optical fiber, a textured surface on the semiconductor device, a grating (fabricated or mounted on the semiconductor device), a prism (fabricated or mounted on the semiconductor device), a lens (fabricated or mounted on a surface of the semiconductor device), a thin-film waveguide, and/or a free space transmission medium. Step (c) may further involve selectively applying an electric field that positions the packet in a position where emissions from the packet are substantially blocked, selectively applying an electric field that positions the packet substantially underneath an opaque masking layer on a surface of the semiconductor device, selectively positioning the packet substantially out of alignment with an energy pathway, and/or ceasing application of an electric field to allow the packet to reposition itself in an equilibrium position substantially out of alignment with the energy pathway.

Further specific aspects of the invention relate to optical emitters that include, for example, the following: an optically active region of semiconductor material; a pump, coupled to the optically active region, and configured to produce a packet of minority carriers in the optically active region; and a deflector, configured to selectively produce an electric field capable of displacing the packet of minority carriers. Such emitters may also include an energy pathway, configured to receive optical emissions from at least a portion of the optically active region of the device. Such emitters may modulate optical emissions through the energy pathway by selectively displacing the packet to regions of lesser and greater coupling to the energy pathway, and may further include an opaque mask region disposed over at least a part of the optically active region such that, when the packet is deflected at least partially underneath the mask region, optical emission from the packet into the energy pathway is reduced. The energy pathway may comprise an aperture in the mask region, a thin-film waveguide, a textured surface, a lens, an optical fiber, a grating, a prism, and/or a free space transmission medium. The pump may comprise a CW laser coupled to a part of the optically active region, a pulsed laser coupled to a part of the optically active region, and/or an electrical carrier injector coupled to a part of the optically active region. The deflector includes two electrodes, preferably arranged in substantial parallel alignment, so as to produce a substantially uniform electric field therebetween. One or both of the electrodes may be metal, or a highly doped semiconductor material. The electrode pair may take the form of a structure of interdigitated fingers, and at least one of the electrodes may also function as a mask to at least partially obstruct emissions from the packet when the packet is located at least partially beneath the electrode.

Still further aspects of the invention relate to methods for making an optical emitter device, such as by: forming an optically active region of semiconductor material; forming first and second electrodes proximate to the optically active region; and forming an energy pathway through which a pumping excitation can create an illuminating packet of minority carriers in the optically active region. Forming an energy pathway may involve coupling a semiconductor laser to the optically active region. Such methods may further involve forming a mask region that can be used to selectively obstruct optical emissions from the optically active region.

Yet further aspects of the invention relate to methods for selectively switching an optical input signal to a first or a second output pathway, such as by: coupling the input signal to an optically active region of semiconductor material such that photons from the input signal create packets of minority carriers in the optically active region; selectively applying a routing bias voltage to create an electric field that selectively drifts the minority carrier packets toward the first or second output pathway; and coupling illuminations from recombining minority carriers in the drifting minority carrier packets to the first or the second optical output pathway. Coupling the optical input signal to the optically active region may involve coupling an optical input fiber to the optically active region. Selectively applying a routing bias voltage may involve selectively applying a DC voltage across two electrodes to create the electric field that selectively drifts the minority carrier packets. Coupling illuminations may involve (i) optically coupling the first optical output pathway to receive illuminations from the recombining minority carriers when the electric field selectively drifts the minority carrier packets toward the first output pathway and/or (ii) optically coupling the second optical output pathway to receive illuminations from the recombining minority carriers when the electric field selectively drifts the minority carrier packets toward the second output pathway.

Still further aspects of the invention relate to optical signal routing devices for selectively routing an optical input signal to one of first and second (or more) optical output pathways, which devices may include: an optically active semiconductor region comprising at least (i) an input receiving portion, (ii) a first output coupling portion, and (iii) a second output coupling portion; an input coupling pathway for configured to couple the optical input signal to the input receiving portion; at least two electrodes configured to selectively drift minority carriers created in the input receiving portion to the first or the second output coupling portions; and first and second output coupling pathways configured to couple emissions from recombining minority carriers in the first and second output coupling portions to the first and second optical output pathways. The optically active region may comprise a grown region of p-type direct bandgap semiconductor material. The input coupling pathway may include an optical fiber coupling configured to couple the optical input signal, carried on an optical fiber, to the input receiving portion of the optically active region. And the first and second output coupling pathways may include optical fiber couplings configured to couple emissions created in the first and second output coupling portions to respective first and second optical output fibers.

Additional aspects of the invention relate to methods of generating a high-speed optical pulse, for example by: exciting minority carriers in an optically active semiconductor material; maintaining a bias voltage across first and second electrodes such that the excited minority carriers drift toward the first electrode to a position in which photoluminescence from ongoing recombination of the minority carriers is substantially obstructed; and rapidly reversing the bias voltage across the electrodes so as to cause the minority carriers to rapidly drift toward the second electrode, first passing through a region in which photoluminescence from ongoing recombination of the minority carriers is substantially unobstructed, then settling in a region in which photoluminescence from ongoing recombination of the minority carriers is substantially obstructed. Exciting minority carriers may involve pumping the semiconductor material with a continuous laser source, pumping the semiconductor material with a pulsed laser source, and/or electrically injecting minority carriers into the semiconductor material. The first electrode may be used to obstruct photoluminescence from the recombining minority carriers when the bias voltage drifts the minority carriers substantially underneath the first electrode, and the second electrode may be used to obstruct photoluminescence from the recombining minority carriers when the bias voltage drifts the minority carriers substantially underneath the second electrode. Such methods may further entail rapidly restoring the bias voltage across the electrodes so as to cause the minority carriers to rapidly drift back toward the first electrode, first passing through the region in which photoluminescence from ongoing recombination of the minority carriers is substantially unobstructed, then settling in the region in which photoluminescence from ongoing recombination of the minority carriers is substantially obstructed.

Yet still further aspects of the invention relate to methods for performing a parallel-to-serial conversion of a plurality of parallel optical input signals, for example by: providing a series of equally-spaced couplings, arranged in a first linear direction, to couple each of the plurality of parallel optical input signals to a corresponding region of an optically active semiconductor material such that the coupled optical input signals can optically excite minority carriers in the corresponding regions; providing an electric field that drifts minority carriers substantially in the first linear direction toward an output coupling region of the semiconductor material; and serializing the plurality of optical input signals by sequentially drifting distributions of optically excited minority carriers produced by the coupled optical input signals past the output coupling region, thereby serially coupling the plurality of optical input signals to the optical output coupling region. The parallel optical input signals may be provided via single-mode optical fibers, and/or the optical output coupling region may couple to the single-mode optical output fiber. The parallel optical input signals may be provided via multi-mode optical fibers, and/or the optical output coupling region may couples to a multi-mode optical output fiber. Or the optical input signals may be coupled to the regions of optically active material via a free-space transmission medium.

### DESCRIPTION OF THE FIGURES

FIG. 1 depicts an exemplary energy band diagram for a homojunction LED in GaAs. Minority carriers are allowed to diffuse across the depletion region after an external bias voltage is applied. Subsequently they are allowed to recombine with majority carriers resulting in photon generation. Reverse band bending occurs near the surface of the diode due to Fermi level pinning, which captures carriers at the surface degrading luminescence efficiency.

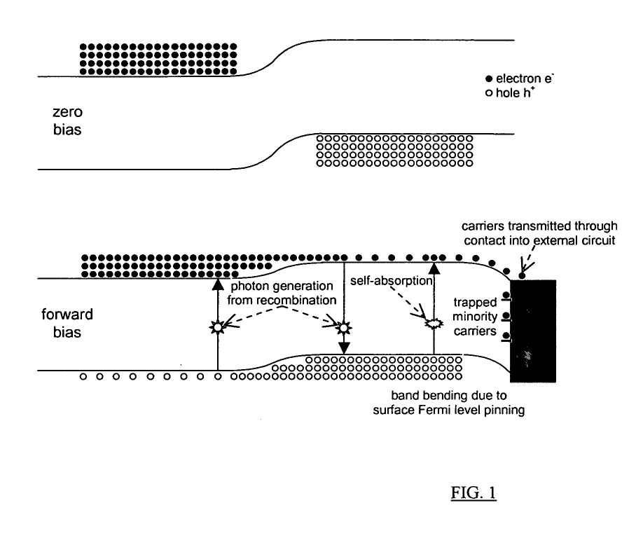

FIG. 2 depicts an exemplary energy band diagram for a GaAs/AlGaAs double heterostructure LED. Minority carriers are confined to the active region by the two heterojunctions.

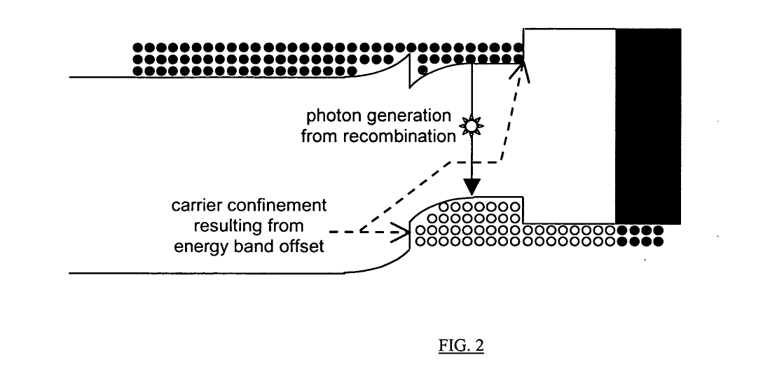

FIG. 3 depicts the escape and total internal reflection of photons generated within the active region of an GaAs LED. Note that the rays falling within the escape cone will transmit into air, while those outside the cone will continue to reflect until they are eventually are reabsorbed by the semiconductor.

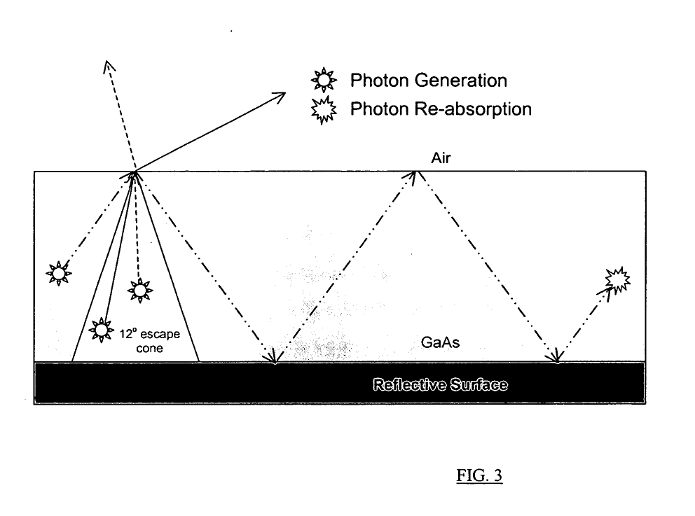

FIGS. 4A-C depcit examples of techniques to increase the extraction efficiency of LEDs: a) textured top surface coupled with a reflective bottom surface. Rays falling outside the escape cone are deflected by texture, reflected by bottom surface into the escape cone. b) Resonant cavity changes optical density of states to increase emission within the escape cone. c) Index matched lens increase the effect escape cone.

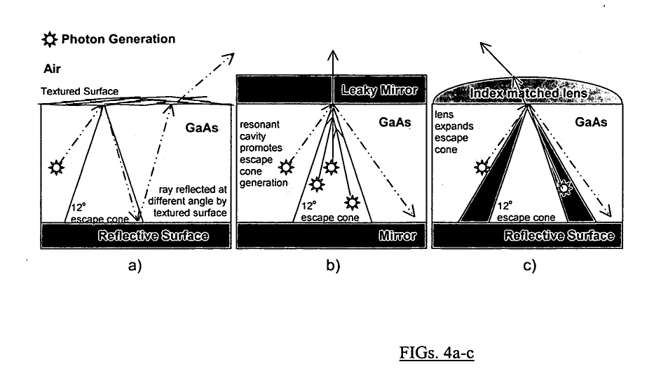

FIG. 5 depicts the theoretical dynamic response of an LED to a pre-emphasis drive current pulse. The rise-time of the LED doped to N_{A=}10¹⁷ cm⁻³ is decreased significantly by using pre-emphasis and is equivalent to the LED doped N_{A}=10¹⁹ cm³ using the standard rectangular pulse. The fall-time of the N_{A}=10¹⁷ cm⁻³ remains unaffected by the pre-emphasis pulse and is still much longer than the heavier doped LED.

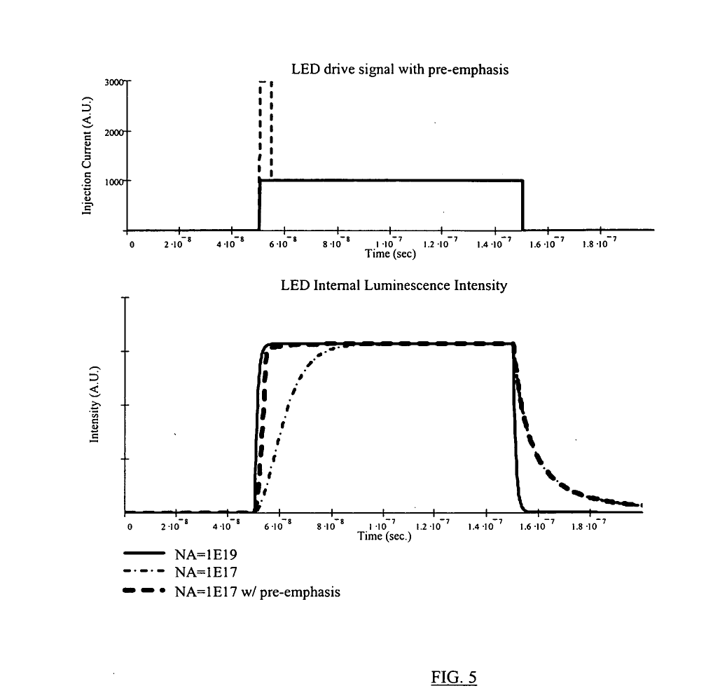

FIG. 6 depicts the theoretical fall-time reduction accomplished by use of a post-emphasis reverse bias current. The negative flowing current rapidly removes carriers from the active region before they can recombine, effectively quenching the optical output.

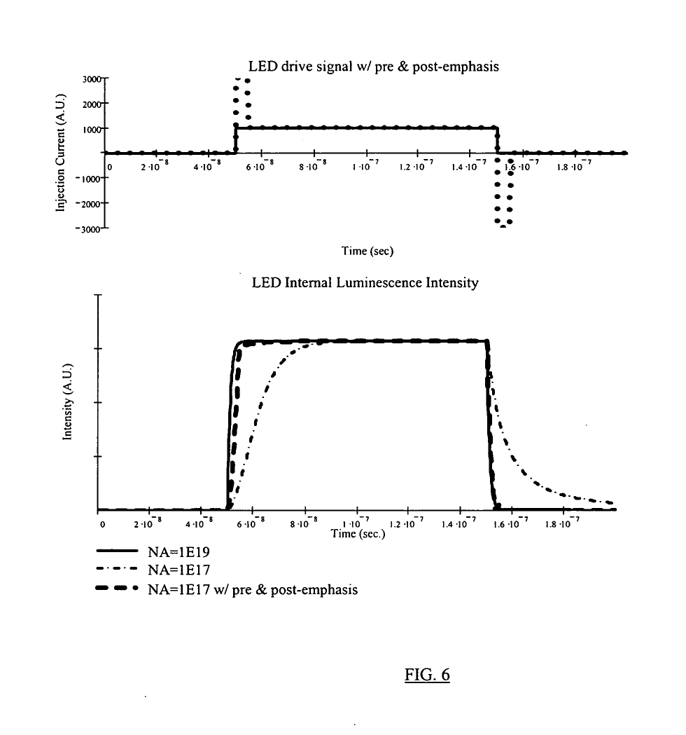

FIGS. 7A-C conceptually illustrate the basic operation of an exemplary FAST device.

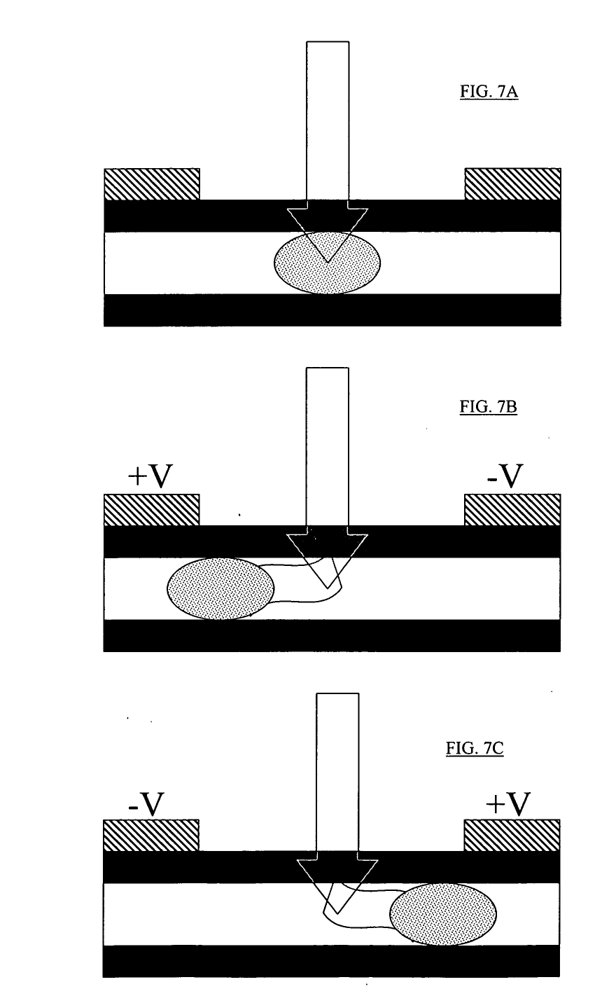

FIGS. 8A-D contain further conceptual illustrations of the basic operation of an exemplary FAST device. Black arrows point in the direction of the electron drift. The figures show laser excitation and PL emission: (a) under zero bias, (b) contact shadowing and attenuation of external PL emission under DC bias, (c) transient response (t0<t1<t2) of PL emission and optical pulse generation due to a switch in applied bias polarity, and (d) steady state at applied bias.

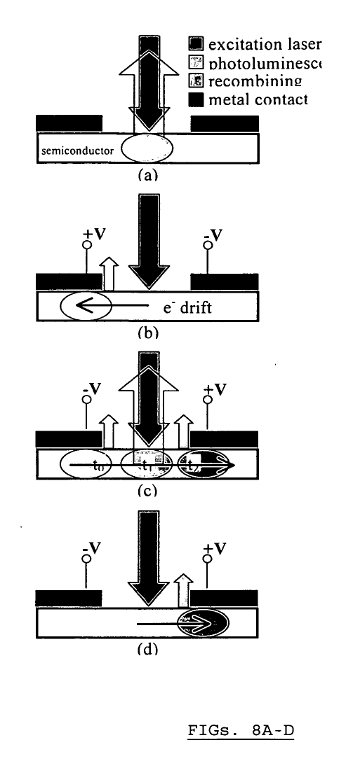

FIGS. 9A-E depict the operation of an exemplary FAST-based, four-channel optical routing device.

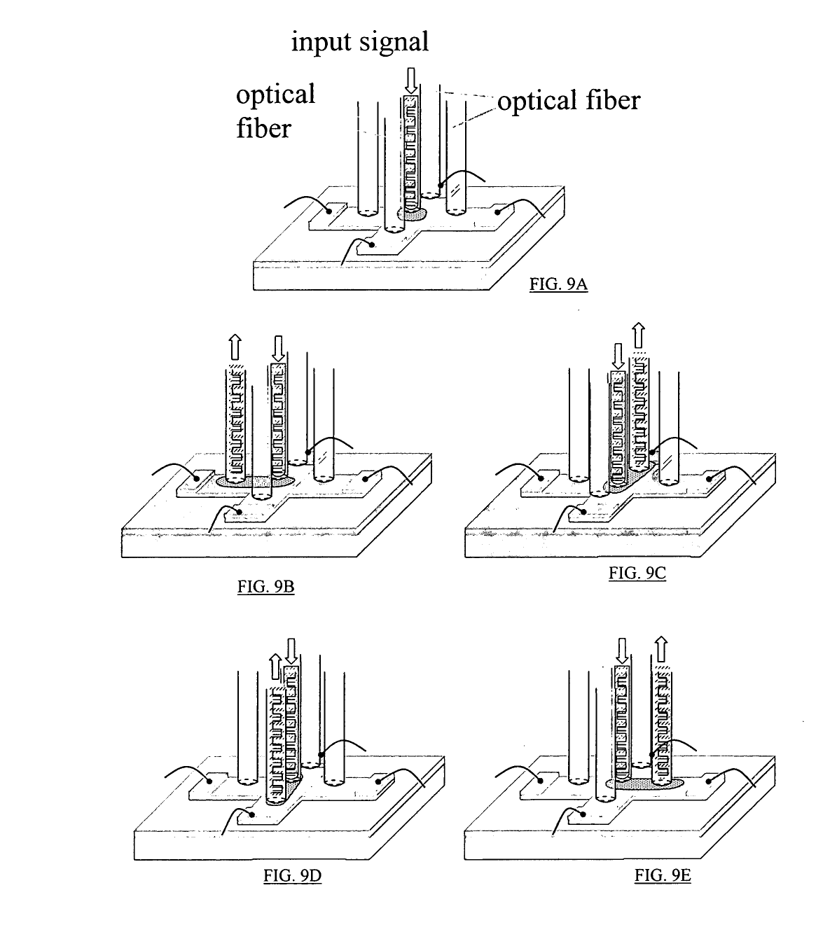

FIG. 10 depicts the structure and operation of an exemplary FAST-based parallel-to-serial converter.

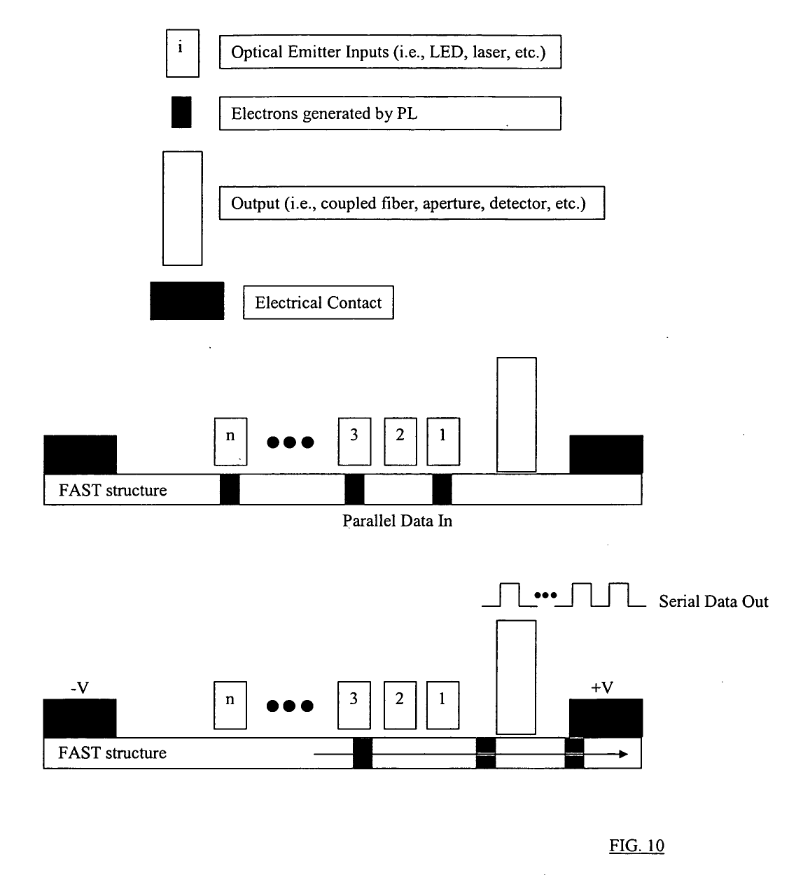

FIGS. 11A-D show spatial modulation and contact shadowing of PL emission for Example 1 under different applied bias voltages. The bias was applied to the electrical probes visible on the top left and lower right contacts: (a) zero bias, (b) 2.5 V, (c) 10 V, and (d) 20 V. For all four conditions, the excitation laser is focused in the center of the structure.

FIG. 12 depicts the experimental setup for Example 2.

FIG. 13 shows the spectral intensity of PL emission as a function of voltage for Example 2. As the applied bias is increased, the emission intensity is reduced by aperture selecting transport. The shift in the peak intensity wavelength is most likely due to the Stark effect.

FIG. 14 shows PL spectral intensity for the modulation doped sample of Example 2. Note that as the modulation doping was increased both the minority carrier lifetime and quantum efficiency decreased.

FIG. 15 depicts the experimental setup for measurement of spatial displacement of photoluminescence as a function of applied voltage in Example 3.

FIG. 16 shows the measured spatial displacement of photoluminescence as a function of applied voltage in Example 3.

FIG. 17 depicts a block diagram of a time resolved photoluminescence (“TRPL”) system used in Example 4. The system uses photon counting to generate histograms that represent the temporal pulse response of the photoluminescence generated by a 30 ps laser pulse.

FIG. 18 shows measurements of effective carrier lifetime as a function of applied voltage in Example 4.

FIG. 19 shows measurements from the all-optical Haynes Shockley experiment of Example 5. Top and bottom waveforms are generated by optical probes separated by 50 microns.

FIG. 20 shows Relative PL signal intensity versus time for the measurements of Example 5. Note the absence of significant diffusion.

FIGS. 21A-B depict the exemplary solid-state optical routing (“SSOR”) device of Example 6.

FIG. 22 shows a band diagram for the optical channel of the SSOR device of Example 6.

FIGS. 23A-D show the behavior of the SSOR device of Example 6.

### DESCRIPTION OF EXEMPLARY EMBODIMENTS

### Example 1

Test structures were fabricated from solid source MBE grown Al_{.90}Ga_{.10}As/GaAs/Al_{.90}Ga_{.10}As double heterostructures. The top and bottom Al₀₉₀Ga_{.10}As barrier layers were 25 and 50 nm thick, respectively, and were incorporated to reduce surface recombination effects and confine the photo-generated electrons within a 100 nm p-type GaAs active layer. The GaAs layer was modulation doped to be approximately 2×10¹⁸ cm⁻³ by doping adjoining AlGaAs regions to approximately N_{A}=10¹⁹.

The minority carrier lifetime of the active layer was measured with time resolved photoluminescence to be approximately 4 ns. Consequently, the diffusion length will be approximately one micron, which helps maintain a dense packet of radiatively recombining carriers. Additionally, 50 nm of Al_{.50}Ga_{.50}As along with a 10 nm GaAs capping layer were grown on top of the structure to reduce surface oxidation. Large Al compositions (≧90%) were employed to reduce absorption of the pump laser light in the cladding regions. Mesa structures were etched into van der Pauw patterns on the wafer and Ti:Au non-alloyed electrical contacts were deposited and lithographically defined on top of the mesas. The central opening in the van der Pauw patterns were approximately 100 μm in diameter. The symmetric contact arrangement and the clear central region in the van der Pauw formed an aperture ideal for observing the effects of the lateral electric field on the PL emission. A diode laser was focused to a spot in the center of the van der Pauw for photo-generation of electrons (dia<100 μm, λ=660 nm, Pₚᵤₘₚ=9.3 mW).

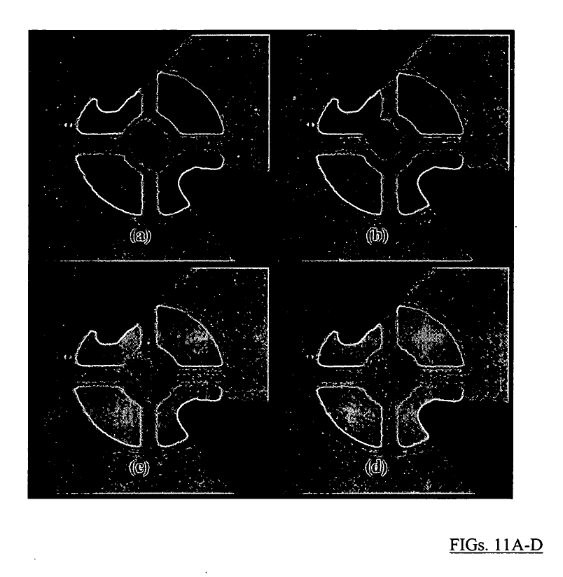

Images were taken with a silicon CCD microscope camera of the PL emission spot (λ_{center}˜870 nm) transmitted from the surface of the semiconductor. A colored glass filter was used to remove the excitation laser light from the images. FIGS. 11A-D clearly demonstrate that when a bias voltage was applied to the electrodes, the PL emission spot was swept towards the positive voltage terminal. As this voltage was increased, the PL spatial displacement continued to increases until it appeared to be nearly completely under the positive electrode. When a slowly varying voltage ramp was applied to the electrodes (30Vₚ₋ₚ, <1 Hz), the PL spot scanned back and forth smoothly between the two contacts, while the pump laser stayed stationary, focused in the center of the structure.

### Example 2

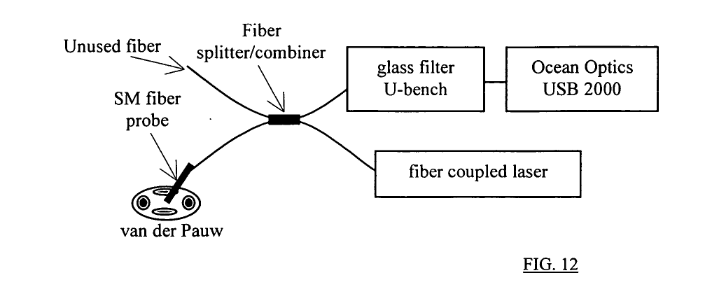

To investigate the utility of the FAST concept for modulating the intensity of optical emitters, the PL spectral intensity profile was measured as a function of the applied voltage. The external pump laser was replaced in this measurement with a fiber pump/probe apparatus (FIG. 12). The procedure insured that the collected PL emission was centered directly over the photo-generation region and precluded any shadowing of the pump source by the probe. The core of a single mode 5 μm diameter fiber was placed in direct contact with the center of the van der Pauw structure. A fiber splitter/combiner was integrated into the measurement setup to connect a fiber pigtailed pump laser to the probe. A U-bench with a colored glass filter removed the laser emission from the spectrum, and an Ocean Optics USB 2000 fiber coupled optical spectrometer measured the PL spectral response. Note that in the experiment discussed previously, the metal contacts were used to create the aperture mask to attenuate the optical emission. In this measurement, the fiber probe itself functions as the exit aperture. Thus, as the fiber laser pumped the sample in a single spot, the collected PL intensity could be modulated by sweeping the packet from under the fiber core.

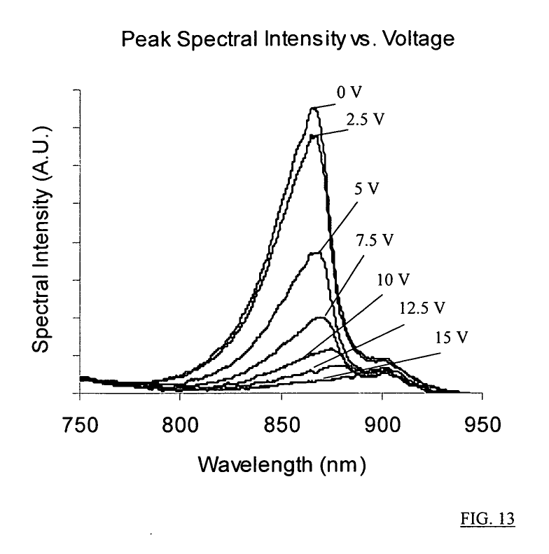

The spectral response was recorded for several DC bias voltages between 0 and 15 V, and the relative PL intensity was significantly reduced as the bias voltage increased (FIG. 13). Although this is only a relative measurement, the observation suggests that the selectable aperture action can easily reduce the emission intensity by nearly an order of magnitude. Notice that the attenuation effects between 2.5 V and 5 V appear to be nonlinear, but at higher applied voltages a more linear relationship exists.

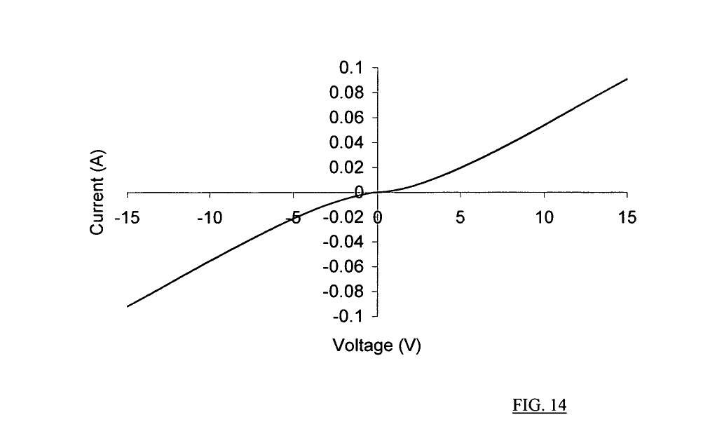

The explanation for this phenomenon becomes clear when the current versus voltage characteristics for the structure is examined (FIG. 14). Note that at lower voltages there exists a slight non-linear I-V consistent with back-to-back Schottky diodes. The behavior is not surprising for non-alloyed metal contacts to p-type AlGaAs. The slightly non-linear I-V should be directly related to the minority carrier current. The non-linearity would reduce the sweeping velocity at lower voltages and explain the non-linear emission intensity versus voltage observed. However, once the Schottkys are fully rectifying, the structures' I-V behavior becomes very linear and exhibits a resistive behavior. Likewise, the PL quenching effect appears to operate more linearly in this region.

Consistent with the Stark effect, a slight shift was observed in peak emission intensity to longer wavelengths as the bias voltage was increased. The effect was observed to increase in the 100 Å and 50 Å superlattice structures. Interestingly, in these structures, the side-to-side sweeping characteristic was not observed. Instead, the PL emission in the center of the structure was rapidly extinguished once the lateral voltage was applied, which suggests that lateral carrier separation within the well is precluding any recombination once the carrier sweeping begins.

### Example 3

A series of experiments were designed to quantify more specifically the temporal and spatial displacement capabilities of the FAST process. The first measurement scanned a single mode fiber probe along the axis of CWPL displacement for various voltages, and measured the relative output power with an optical power meter.

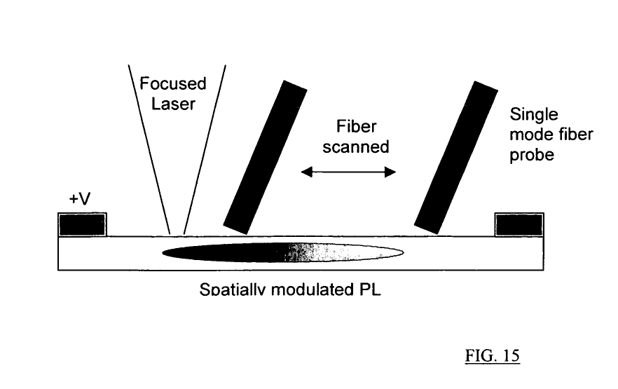

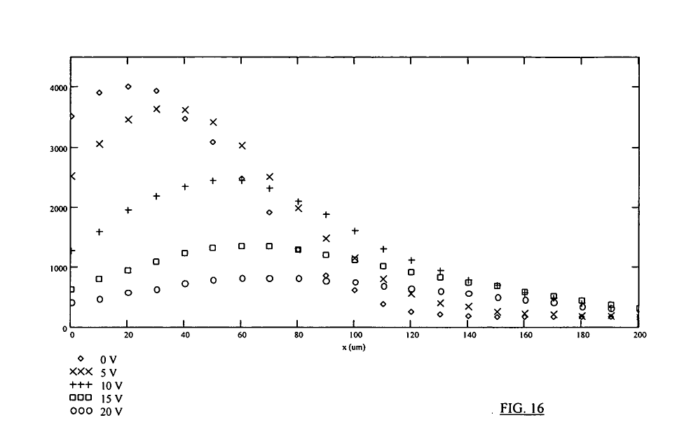

FIG. 15 illustrates the experimental setup for the measurement, and the experimental results are presented in FIG. 16. Note that there is a clear spatial shift in the peak intensity, which suggests that the FAST concept can be used in an optical routing switch.

### Example 4

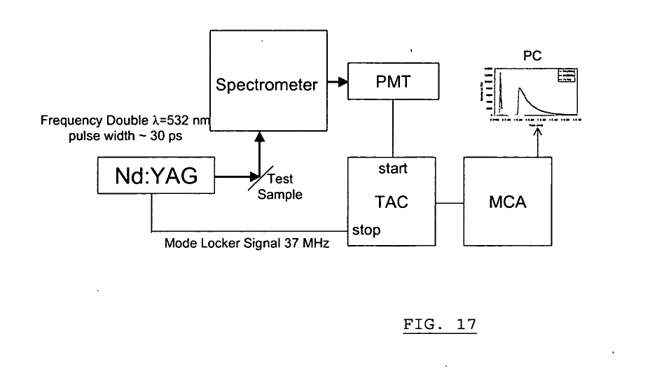

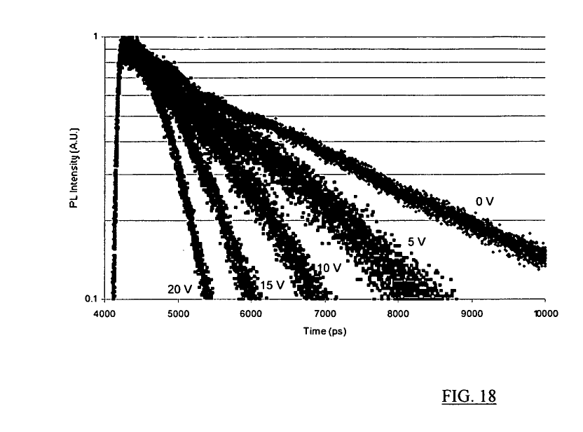

Time resolved photoluminescence measurements were performed on the test structure as a function of voltage. The measurements were performed on the same TRPL system of FIG. 17. The test sample was pumped and probed with a single-mode optical fiber probe in the center of the van der Pauw structure under various DC biases. The results of these measurements are presented in FIG. 18. The effective lifetime decreases significantly as the voltage is increased. Note the shape of the PL temporal signature at higher applied voltages. Unlike the exponential decay typically observed in TRPL measurements, a bell shaped roll-off is observed, which would be consistent with the theory that the speed of FAST concept is determined by the sweeping of a Gaussian-shaped packet of minority carriers away from the aperture defined by the fiber.

### Example 5

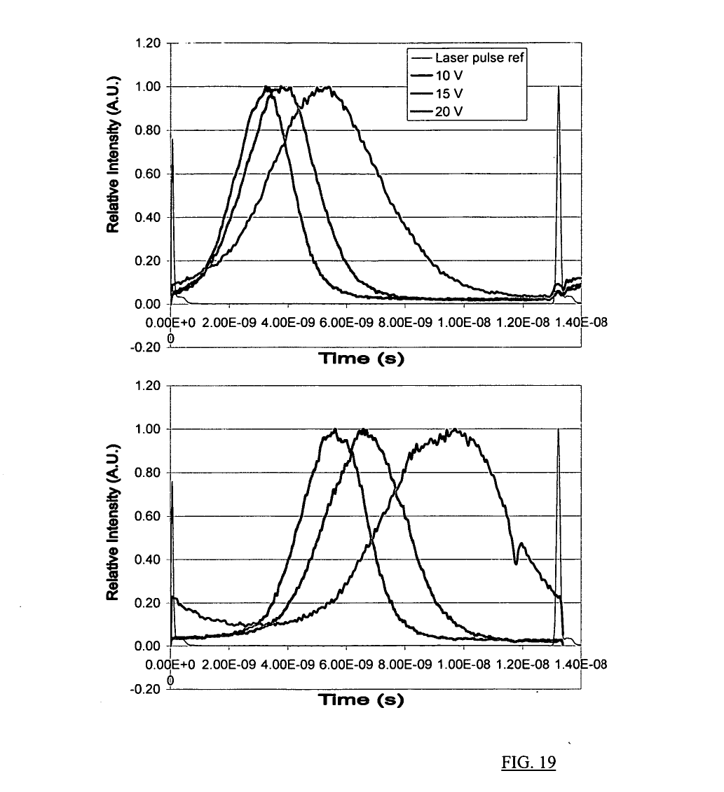

An all-optical variation of the Haynes-Shockley experiment was performed. The sample was pumped and probed between two metal electrodes spaced 250 microns apart. The voltage between the two electrodes was varied between 0 and 20 volts, resulting in a maximum electric field of 800 V/cm. The pump pulse laser beam (l=532 nm, tpulse=30 ps) was focused by a microscope objective to an approximately 35 micron diameter and was assumed to be Gaussian in shape. The center of the beam spot was offset from one of the electrodes by 50 microns. The PL emission was collected with a single-mode (5 micron) optical fiber probe, offset from the pump beam along the axis of the applied electric field and the minority carrier drift vector. The probe was connected to the spectrometer, PMT, TAC setup of FIG. 17. The fiber probe was positioned at 50 microns, 75 microns and 100 microns from the center of the pump focus, and TRPL measurements were recorded at 0V, 5V, 10V, 15V, and 20V for each fiber probe position. Samples of the optical waveforms are presented in FIG. 19.

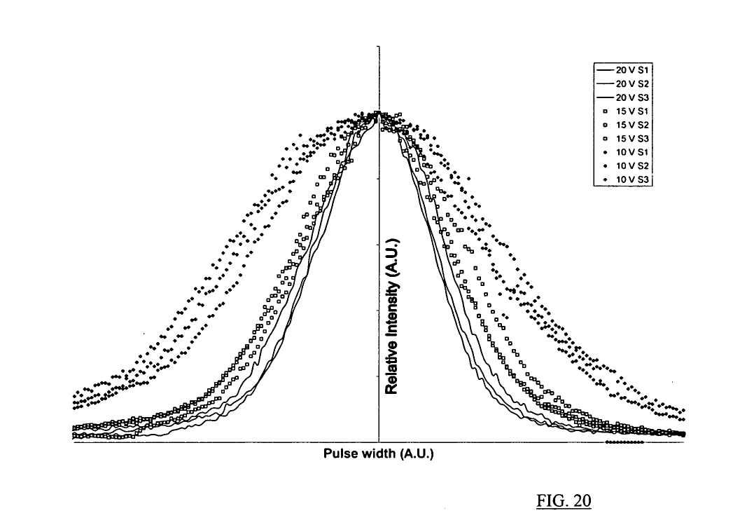

Since the voltage position and time are known parameters for this measurement, the velocity can be measured and subsequently the field dependent mobility can be determined. The mobility is observed to drop from 3000 cm²/(sec·V) to almost 2500 cm²/(sec·V) over the electric field range studied. The source of this decrease is likely due to sample heating resulting from the higher current flow at increased voltage. It is important to note that the difference in width of the various pulses is related to the relative velocity difference of the signals and not diffusion. FIG. 20 shows the various pulses referenced to their peak intensity. It is clear that pulse shape broadening is insignificant at the three probe locations.

### Example 6

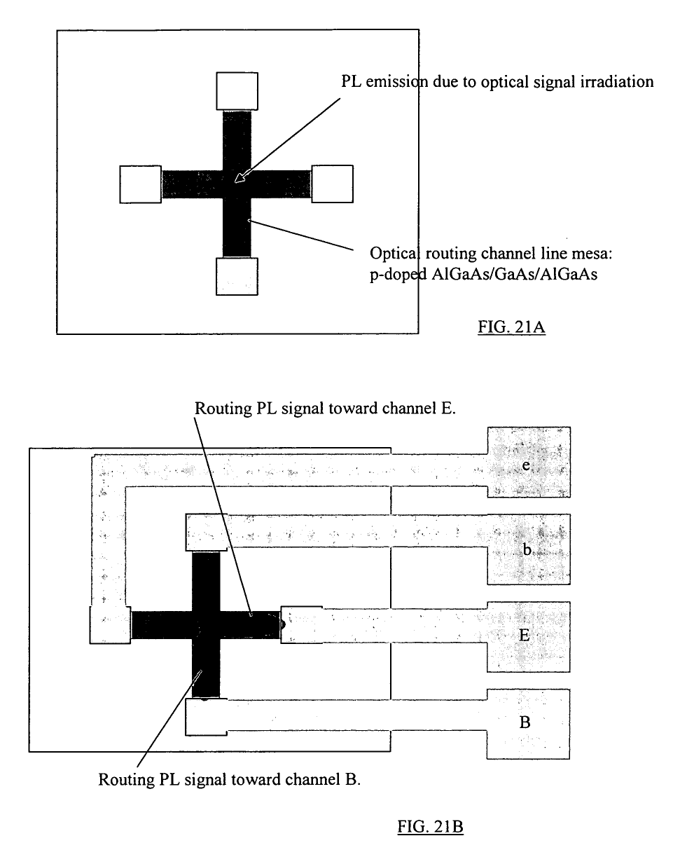

A schematic illustration of a four-channel solid-state optical routing (“SSOR”) device is shown in FIGS. 21A-B. An optical fiber is located on the center of the channel that provides optically modulated signals as an input signal source. The optical input signals generate minority carriers in the channel, and the carriers are drifted toward channel E with an electric field between pads e and E. The minority carries recombine with majority carriers after drifting and emit photons in channel E region. Since an optical fiber is located on the channel E, PL emission in the channel E is probed with the fiber as the output signals.

For a wavelength of the input signal, an appropriate direct bandgap material is chosen as a channel layer in order to effectively absorb the input light and generate PL emission. When a material with minority carrier radiative lifetime of Tr˜2 ns and a mobility μ is used for the channel, the average displacement x from the input spot is obtained by x=μE Tr under an electric field E. For a minority carrier mobility of μ˜2000 cm2/V-s and an electric field of E=2 kV/cm, we can expect to achieve a displacement of PL emission from the input spot to be x=80 (μm). This value is sufficient to permit coupling of another optical fiber to probe the output PL signal. The approximate time delay of the signal is obtained by d/μE for a distance d between the input and output fibers.

A high quality heterostructure is needed to provide higher-minority carrier mobility and efficient radiative recombination in the channel layer. P-type modulation doped heterostructures were designed for the purpose.

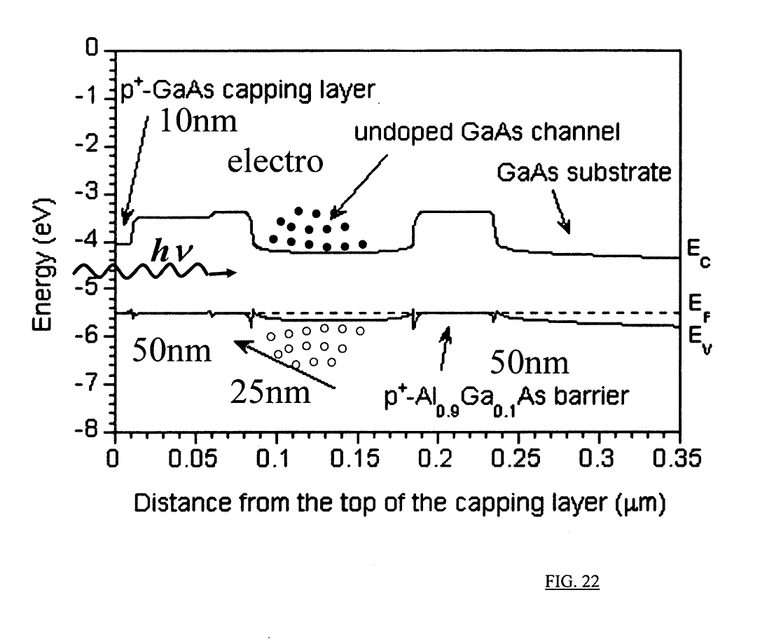

P-GaAs(10 nm)/p-A_{10.5}Ga_{0.5}As(50 nm)/p-A_{10.9}Ga_{0.1}As(25 nm)/undoped GaAs(100 nm)/p-A_{10.9}Ga_{0.1}As(50 nm) layers were grown on semi-insulating GaAs (001) substrate. The top GaAs layer and three AlGaAs layers were doped with beryllium (Be) atoms at 2×1019 cm-3, which was designed to provide a high density of free holes in the undoped GaAs channel layer to be approximately 1×1018 cm-3 and allow a high electron mobility in the channel layer. A GaAs capping layer is for reducing oxidation of the sample surface. The band diagram of the structure at equilibrium is shown in FIG. 22. The A10.9Ga_{0.1}As barrier layers are employed to confine photo-generated electrons in the channel layer by forming a conduction band offset for the GaAs channel layer. Bar shape mesa are formed and etched down to the substrate with photolithography and a chemical etching process. Two Ti/Au non-alloyed electrical contacts were formed on the top of the mesa with a spacing of 220 μm. The minority carrier (electron) radiative lifetime Tr of the GaAs channel layer measured with time resolved photoluminescence is 4.18 ns at room temperature.

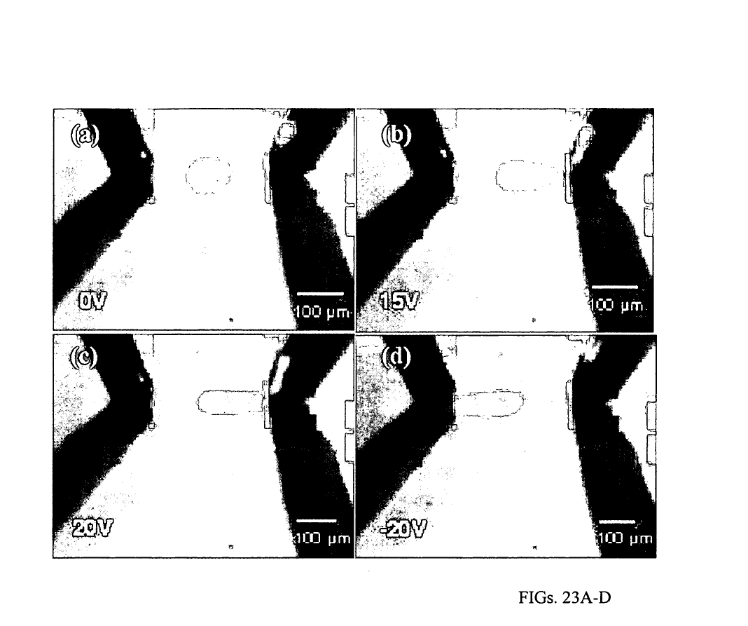

A diode laser was focused onto the surface of a mesa-etched bar for photo-pumping of electron-hole pairs (φ<100 μm, λ=660 nm, P˜1 mW). Photographs of PL emission from a sample with and without DC bias are shown in FIGS. 23A-D, indicating applied biases (left probe: ground). At room temperature, a bright PL spot is seen between the two probes, showing a round shape with a 100 μm diameter at zero bias (FIG. 23A). The bright spot indicates sufficient reduction of nonradiative recombination in the channel layer. The typical peak wavelength measured is 871 nm. When DC bias is applied to the probes, the spot moves toward the positively biased probe (right side) and the displacement from the original spot increases with the applied bias (FIGS. 23B-C). This indicates that the photo-generated minority carriers are electrons, since the PL spot drifts toward the positively biased probe. Therefore, the concept of minority carrier lateral drift before the recombination is confirmed. The results also reveal that the maximum displacement of PL spot at 20 V is more than 100 μm from the original spot. This distance is sufficient to mount a single or multi-mode optical fiber as an output signal probe. Assuming that the radiative lifetime of the electrons in the channel layer is constant (Tr=4 ns), the electron drift velocity is calculated to be 2.5×10⁶ cm/s. When a reverse bias (−20V) was applied to the electrodes, the PL spot is immediately swept out toward the left side as shown in FIG. 22D. When a drive-circuit with gigahertz operation is used for the device, nanosecond-scale dynamic routing is possible. As the device operates without selection of wavelength, this device would be suitable for the signal routing at the end stage of a wavelength division multiplexing (“WDM”) system for short distance communication.

Applications of FAST: Optical emitter/modulators developed using the FAST concept can be appropriate for utilization in various optical data link applications. Examples of these links include chip-to-chip optical interconnects using fiber optic cables, thin film waveguides, or free space mediums. Additionally, FAST devices may be appropriate in optical data links for board-to-board, backplane-to-backplane, or computer-to-computer digital data transmission. These devices can be appropriate for long and short haul optical fiber telecommunications systems. For chip-to-chip applications, a separate, higher-energy pump beam could be transmitted to the FAST devices to generate the charge packet through the same waveguide that is utilized to transmit data between the transmitting and receiving chips. In such case, filters would be included before the detectors to remove the pump beam from the signal.

Although the described embodiments of the invention generally utilize horizontal displacement of the carrier packets, FAST devices may also be realized using vertical carrier displacement.

Finally, applicants note that the FAST concept may be applied to create high-speed Si-based optical emitters, switching devices, etc. using recently-reported, high quantum efficiency, optically-active Si to provide the optically-active region in a FAST device. (See T. Trupke, et al., “Very efficient light emission from bulk crystalline silicon,” Applied Physics Letters, vol. 82:18, May 2003; M. A. Green, et al., “Efficient silicon light-emitting diodes,” Nature, vol. 412, August 2001.)

We claim:

1. A method for modulating optical emissions from a semiconductor device, comprising:
(a) providing an excitation that produces an illuminating packet of charged carriers;
(b) selectively positioning said packet to increase optical emissions from the semiconductor device; and,
(c) selectively positioning said packet to reduce optical emissions from the semiconductor device.

2. A method, as defined in claim 1, wherein at least one of the selective positioning actions of steps (b) or (c) is achieved by selective application of an electric field to the packet.

3. A method, as defined in claim 2, wherein both of the selective positioning actions of steps (b)-(c) are achieved by selective application of an electric field to the illuminating packet.

4. A method, as defined in claim 1, wherein steps (b) and/or (c) are repeatedly performed, in an order determined by an electrical input signal, to produce an optically modulated output signal corresponding to said electrical input signal.

5. A method, as defined in claim 1, wherein providing an excitation comprises pumping said semiconductor device with a continuous laser excitation.

6. A method, as defined in claim 1, wherein providing an excitation comprises pumping said semiconductor device with a pulsed laser excitation.

7. A method, as defined in claim 1, wherein providing an excitation comprises electrically pumping said semiconductor device.

8. A method, as defined in claim 1, wherein step (b) comprises selectively positioning said packet so that its optical emissions for the semiconductor device are substantially unblocked.

9. A method, as defined in claim 8, wherein step (b) further comprises selectively applying an electric field that positions said packet in a position that allows substantial emission from the semiconductor device.

10. A method, as defined in claim 8, wherein step (b) further comprises ceasing application of an electric field to allow said packet to drift to an equilibrium position that allows substantial emission from the semiconductor device.

11. A method, as defined in claim 1, wherein step (b) comprises selectively positioning said packet in substantial alignment with an energy pathway through which optical emissions can escape from the semiconductor device.

12. A method, as defined in claim 11, wherein said energy pathway comprises an optical fiber.

13. A method, as defined in claim 11, wherein said energy pathway comprises a textured surface on the semiconductor device.

14. A method, as defined in claim 11, wherein said energy pathway comprises a grating, fabricated or mounted on the semiconductor device.

15. A method, as defined in claim 11, wherein said energy pathway comprises a prism, fabricated or mounted on the semiconductor device.

16. A method, as defined in claim 11, wherein said energy pathway comprises a lens, fabricated or mounted on a surface of the semiconductor device.

17. A method, as defined in claim 11, wherein said energy pathway comprises a free space transmission medium.

18. A method, as defined in claim 1, wherein step (c) further comprises selectively applying an electric field that positions said packet in a position where emissions from the packet are substantially blocked.

19. A method, as defined in claim 1, wherein step (c) further comprises selectively applying an electric field that positions said packet substantially underneath an opaque masking layer on a surface of said semiconductor device.

20. A method, as defined in claim 1, wherein step (c) further comprises selectively positioning said packet out of alignment with an energy pathway.

21. A method, as defined in claim 20, wherein said energy pathway comprises an optical fiber.

22. A method, as defined in claim 20, wherein said energy pathway comprises a textured surface on the semiconductor device.

23. A method, as defined in claim 20, wherein said energy pathway comprises a thin-film waveguide.

24. A method, as defined in claim 20, wherein said energy pathway comprises a free space transmission medium.

25. A method, as defined in claim 20, wherein said energy pathway comprises a grating, fabricated or mounted on a surface of the semiconductor device.

26. A method, as defined in claim 20, wherein said energy pathway comprises a prism, fabricated or mounted on a surface of the semiconductor device.

27. A method, as defined in claim 20, wherein step (c) further comprises selectively applying an electric field to position said packet substantially out of alignment with said energy pathway.

28. A method, as defined in claim 20, wherein step (c) further comprises ceasing application of an electric field to allow said packet to reposition itself in an equilibrium position substantially out of alignment with said energy pathway.

29. A optical emitter device, comprising:
an optically active region of semiconductor material;
a pump, coupled to said optically active region, and configured to produce a packet of minority carriers in said optically active region; and,
a deflector, configured to selectively produce an electric field capable of displacing the packet of minority carriers.

30. A device, as defined in claim 29, further comprising:
an energy pathway, configured to receive optical emissions from at least a portion of said optically active region of said device.

31. A device, as defined in claim 30, wherein said device modulates optical emissions through said energy pathway by selectively displacing said packet to regions of lesser and greater coupling to said energy pathway.

32. A device, as defined in claim 31, further comprising an opaque mask region disposed over at least a part of said optically active region such that, when said packet is deflected at least partially underneath said mask region, optical emission from the packet into the energy pathway is reduced.

33. A device, as defined in claim 32, wherein said energy pathway comprises an aperture in said mask region.

34. A device, as defined in claim 33, wherein said energy pathway further comprises a textured surface.

35. A device, as defined in claim 33, wherein said energy pathway further comprises a thin-film waveguide.

36. A device, as defined in claim 33, wherein said energy pathway further comprises an optical fiber.

37. A device, as defined in claim 33, wherein said energy pathway further comprises a grating.

38. A device, as defined in claim 33, wherein said energy pathway further comprises a prism.

39. A device, as defined in 33, wherein said energy pathway further comprises a free space transmission medium.

40. A device, as defined in claim 31, wherein said energy pathway comprises a textured surface.

41. A device, as defined in claim 31, wherein said energy pathway comprises a lens.

42. A device, as defined in claim 31, wherein said energy pathway comprises an optical fiber.

43. A device, as defined in claim 31, wherein said energy pathway further comprises a grating.

44. A device, as defined in claim 31, wherein said energy pathway further comprises a prism.

45. A device, as defined in 31, wherein said energy pathway comprises a free space transmission medium.

46. A device, as defined in claim 31, wherein said energy pathway comprises a filter that filters emissions from the pump, but passes emissions from the packet.

47. A device, as defined in claim 29, wherein said pump comprises a CW laser, coupled to a part of said optically active region.

48. A device, as defined in claim 29, wherein said pump comprises a pulsed laser, coupled to a part of said optically active region.

49. A device, as defined in claim 29, wherein said pump comprises an electrical carrier injector, coupled to a part of said optically active region.

50. A device, as defined in claim 29, wherein said deflector comprises two electrodes.

51. A device, as defined in claim 50, wherein said two electrodes are substantially parallel, so as to produce a substantially uniform electric field therebetween.

52. A device, as defined in claim 50, wherein at least one of said electrodes comprises metal.

53. A device, as defined in claim 50, wherein at least one of said electrodes comprises a highly doped semiconductor material.

54. A device, as defined in claim 50, wherein said electrodes comprise a structure of interdigitated fingers.

55. A device, as defined in claim 50, wherein at least one of said electrodes also functions as a mask to at least partially obstruct emissions from said packet when said packet is located at least partially beneath said electrode.

56. A method for making an optical emitter device, said method comprising:
forming an optically active region of semiconductor material;
forming first and second electrodes proximate to said optically active region; and,
forming an energy pathway through which a pumping excitation can create an illuminating packet of minority carriers in said optically active region.

57. A method for making an optical emitter device, as defined in claim 56, wherein forming an energy pathway further comprises coupling a semiconductor laser to said optically active region.

58. A method for making an optical emitter device, as defined in claim 56, further comprising forming a mask region that can be used to selectively obstruct optical emissions from said optically active region.

59. A method for selectively switching an optical input signal to a first or a second output pathway, the method comprising:
coupling the input signal to an optically active region of semiconductor material such that photons from said input signal create packets of minority carriers in said optically active region;
selectively applying a routing bias voltage to create an electric field that selectively drifts said minority carrier packets toward the first or second output pathway; and,
coupling illuminations from recombining minority carriers in said drifting minority carrier packets to said first or said second optical output pathway.

60. A method, as defined in claim 59, wherein coupling said optical input signal to said optically active region comprises coupling an optical input fiber to said optically active region.

61. A method, as defined in claim 59, wherein selectively applying a routing bias voltage comprises selectively applying a DC voltage across two electrodes to create the electric field that selectively drifts said minority carrier packets.

62. A method, as defined in claim 59, wherein coupling illuminations comprises (i) optically coupling said first optical output pathway to receive illuminations from said recombining minority carriers when said electric field selectively drifts said minority carrier packets toward said first output pathway; and (ii) optically coupling said second optical output pathway to receive illuminations from said recombining minority carriers when said electric field selectively drifts said minority carrier packets toward said second output pathway.

63. An optical signal routing device for selectively routing an optical input signal to one of first and second optical output pathways, said device comprising:
an optically active semiconductor region comprising at least (i) an input receiving portion, (ii) a first output coupling portion, and (iii) a second output coupling portion;
an input coupling pathway for configured to couple said optical input signal to said input receiving portion;
at least two electrodes configured to selectively drift minority carriers created in said input receiving portion to said first or said second output coupling portions; and,
first and second output coupling pathways configured to couple emissions from recombining minority carriers in said first and second output coupling portions to said first and second optical output pathways.

64. An optical signal routing device, as defined in claim 63, wherein said optically active region comprises a grown region of p-type direct bandgap semiconductor material.

65. An optical signal routing device, as defined in claim 63, wherein said input coupling pathway comprises an optical fiber coupling configured to couple the optical input signal, carried on an optical fiber, to said input receiving portion of said optically active region.

66. An optical signal routing device, as defined in claim 63, wherein said first and second output coupling pathways comprise optical fiber couplings configured to couple emissions created in said first and second output coupling portions to first and second optical output fibers.

67. A method of generating a high-speed optical pulse, the method comprising:
exciting minority carriers in an optically active semiconductor material;
maintaining a bias voltage across first and second electrodes such that the excited minority carriers drift toward the first electrode to a position in which photoluminescence from ongoing recombination of said minority carriers is substantially obstructed; and,
rapidly reversing the bias voltage across said electrodes so as to cause said minority carriers to rapidly drift toward the second electrode, first passing through a region in which photoluminescence from ongoing recombination of said minority carriers is substantially unobstructed, then settling in a region in which photoluminescence from ongoing recombination of said minority carriers is substantially obstructed.

68. A method, as defined in claim 67, wherein exciting minority carriers comprises pumping the semiconductor material with a continuous laser source.

69. A method, as defined in claim 67, wherein exciting minority carriers comprises pumping the semiconductor material with a pulsed laser source.

70. A method, as defined in claim 67, wherein exciting minority carriers comprises electrically injecting minority carriers into said semiconductor material.

71. A method, as defined in claim 67, wherein said first electrode obstructs photoluminescence from said recombining minority carriers when said bias voltage drifts said minority carriers substantially underneath said first electrode, and said second electrode obstructs photoluminescence from said recombining minority carriers when said bias voltage drifts said minority carriers substantially underneath said second electrode.

72. A method, as defined in claim 67, further comprising:
rapidly restoring the bias voltage across said electrodes so as to cause said minority carriers to rapidly drift back toward the first electrode, first passing through said region in which photoluminescence from ongoing recombination of said minority carriers is substantially unobstructed, then settling in the region in which photoluminescence from ongoing recombination of said minority carriers is substantially obstructed.

73. A method for performing a parallel-to-serial conversion of a plurality of parallel optical input signals, the method comprising:
providing a series of equally-spaced couplings, arranged in a first linear direction, to couple each of said plurality of parallel optical input signals to a corresponding region of an optically active semiconductor material such that said coupled optical input signals can optically excite minority carriers in said corresponding regions;
providing an electric field that drifts minority carriers substantially in said first linear direction toward an output coupling region of said semiconductor material; and,
serializing said plurality of optical input signals by sequentially drifting distributions of optically excited minority carriers produced by said coupled optical input signals past said output coupling region, thereby serially coupling said plurality of optical input signals to said optical output coupling region.

74. A method, as defined in claim 73, wherein said parallel optical input signals are provided via single-mode optical fibers.

75. A method, as defined in claim 74, wherein said optical output coupling region couples to a single-mode optical output fiber.

76. A method, as defined in claim 73, wherein said parallel optical input signals are provided via multi-mode optical fibers.

77. A method, as defined in claim 76, wherein said optical output coupling region couples to a multi-mode optical output fiber.

78. A method, as defined in claim 73, wherein said optical input signals are coupled to said regions of optically active material via a free-space transmission medium.
